(19) United States
(12) Patent Application Publication
(10) Pub. No.: US 2026/0160797 A1
(43) Pub. Date: Jun. 11, 2026

(54) TEST DEVICE, METHOD AND SYSTEM

(71) Applicant: Nuvoton Technology Corporation, Hsinchu Science Park (TW)

(72) Inventor: Cheng-Chih WANG, Jhubei City (TW)

(21) Appl. No.: 19/381,576

(22) Filed: Nov. 6, 2025

(30) Foreign Application Priority Data
Dec. 10, 2024 (TW) 113147770

(51) Int. Cl. G01R 31/28; H01L 21/66

(52) U.S. Cl. CPC G01R 31/2831; H10P 74/273; H10P 74/277

(57) ABSTRACT

A test device including a storage circuit and a processing circuit is provided. The storage circuit stores a machine learning model. In a training mode, the processing circuit loads the machine learning model and inputs wafer acceptance test (WAT) sample data of a sample wafer into the machine learning model to train the machine learning model to predict the process factor of each sample die of the sample wafer. In a test mode, the processing circuit inputs WAT data of a wafer to be tested into the machine learning model to predict the process factor of each die of the wafer to be tested. In the test mode, the processing circuit converts the process factor of each die of the wafer to be tested to generate a trim value and provides the trim value to a function circuit of a corresponding die of the wafer to be tested.

### CROSS REFERENCE TO RELATED APPLICATIONS

This Application claims priority of Taiwan Patent Application No. 113147770, filed on Dec. 10, 2024, the entirety of which is incorporated by reference herein.

### TECHNICAL FIELD

The present disclosure relates to a test device, and, in particular, it relates to a test device that uses a machine learning model to predict the trim values of a wafer.

### BACKGROUND

Finished wafers are regularly distributed with unpackaged dies. In order to ensure that the function circuits of each die operates normally, each die must be tested during a testing period to determine the trim value of each die. This testing process is very lengthy and the cost of the test is high.

### BRIEF SUMMARY

An embodiment of the present disclosure provides a test device comprising a storage circuit and a processing circuit. The storage circuit stores a machine learning model. The processing circuit accesses the storage circuit. In a training mode, the processing circuit is electrically connected to a sample wafer which comprises a plurality of sample dies. In the training mode, the processing circuit loads the machine learning model and inputs wafer acceptance test (WAT) sample data of the sample wafer into the machine learning model to train the machine learning model to predict the process factor of each sample die of the sample wafer. In a test mode, the processing circuit is electrically connected to a wafer which is to be tested and which comprises a plurality of dies to be tested. In the test mode, the processing circuit inputs WAT data of the wafer to be tested into the machine learning model to predict the process factor of each die to be tested. In the test mode, the processing circuit converts the process factor of each die to be tested to generate a trim value and provides the trim value to a first function circuit of a corresponding die to be tested.

A test method is provided. An exemplary embodiment of a test method is described in the following paragraph. In a training mode, the WAT sample data of a sample wafer is input into a machine learning model to train the machine learning model to predict the process factor of each sample die of the sample wafer. In a test mode, the WAT data of a wafer to be tested is input into the machine learning model so that the machine learning model predicts the process factor of each die of the wafer to be tested. In the test mode, the process factor of each die of the wafer to be tested is converted to a trim value, and the trim value is provided to a first function circuit of a corresponding die to be tested.

An embodiment of the present disclosure provides a test system comprises a test platform, a storage circuit, and a processing circuit. The test platform is configured to dispose a sample wafer or a wafer to be tested. The storage circuit stores a machine learning model. The processing circuit accesses the machine learning model. In a training mode, the sample wafer is disposed on the test platform. In the training mode, the processing circuit is electrically connected to the sample wafer which comprises a plurality of sample dies. In the training mode, the processing circuit loads the machine learning model and inputs WAT sample data of the sample wafer into the machine learning model to train the machine learning model to predict the process factor of each sample die. In a test mode, the wafer to be tested is disposed on the test platform. In the test mode, the processing circuit is electrically connected to the wafer which is to be tested and which comprises a plurality of dies to be tested. In the test mode, the processing circuit inputs WAT data of the wafer to be tested into the machine learning model to predict the process factor of each die to be tested. In the test mode, the processing circuit converts the process factor of each die to be tested to generate a trim value and provides the trim value to a first function circuit of a corresponding die to be tested.

Test methods may be practiced by the systems which have hardware or firmware capable of performing particular functions and may take the form of program code embodied in a tangible media. When the program code is loaded into and executed by an electronic device, a processor, a computer or a machine, the electronic device, the processor, the computer or the machine becomes a test device and a test system for practicing the disclosed method.

### BRIEF DESCRIPTION OF THE DRAWINGS

The present disclosure can be more fully understood by reading the subsequent detailed description and examples with references made to the accompanying drawings, wherein:

FIG. 1A is a flowchart of an exemplary embodiment of a test method according to various aspects of the present disclosure;

FIG. 1B is a flowchart of another exemplary embodiment of the test method according to various aspects of the present disclosure;

FIG. 2 is a schematic diagram of an exemplary embodiment of a wafer map according to various aspects of the present disclosure; and

FIG. 3 is a schematic diagram of an exemplary embodiment of a test system according to various aspects of the present disclosure.

### DETAILED DESCRIPTION

The present disclosure will be described with respect to particular embodiments and with reference to certain drawings, but the disclosure is not limited thereto and is only limited by the claims. The drawings described are only schematic and are non-limiting. In the drawings, the size of some of the elements may be exaggerated for illustrative purposes and not drawn to scale. The dimensions and the relative dimensions do not correspond to actual dimensions in the practice of the present disclosure.

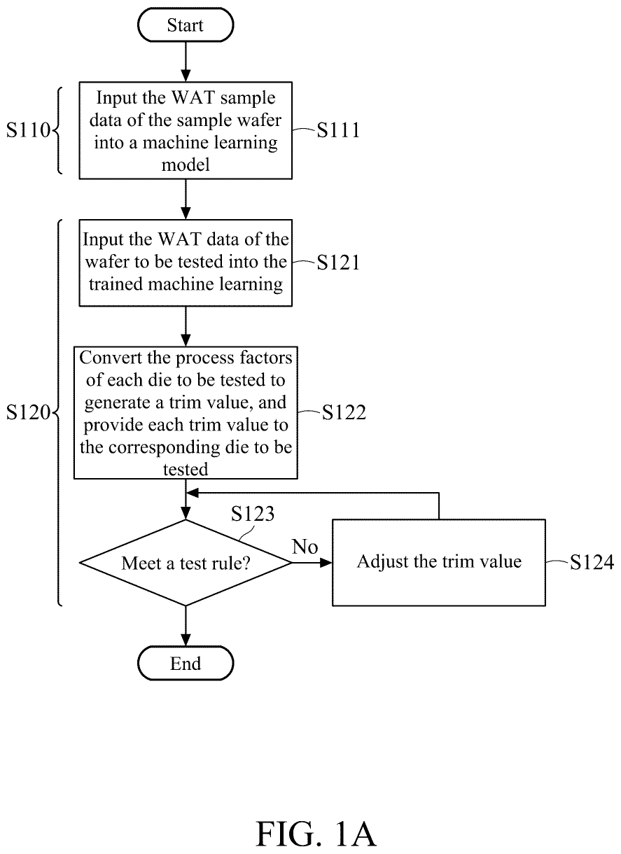

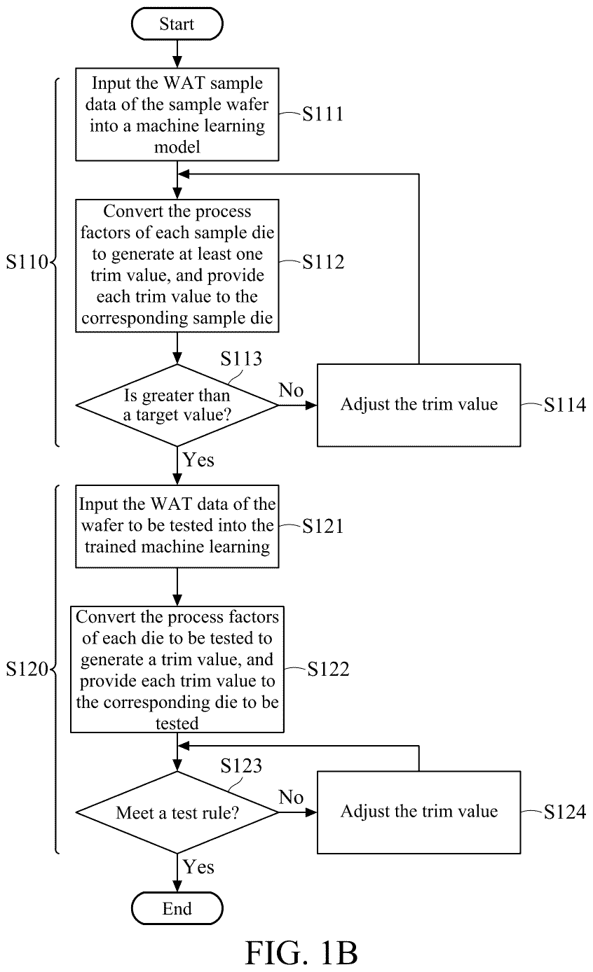

FIG. 1A is a flowchart of an exemplary embodiment of a test method according to various aspects of the present disclosure. The test method may take the form of a program code. When the program code is loaded into and executed by a machine, the machine thereby becomes a test device and a test system for practicing the test method. First, a training operation is performed on a sample wafer in a training mode (step S110). The sample wafer comprises a plurality of sample dies.

The wafer acceptance test (WAT) sample data of the sample wafer is input into a machine learning model (step S111). The machine learning model predicts the process factor of each sample die of the sample wafer. In one embodiment, in order to test the process yield of the sample wafer, the manufacturer of the sample wafer disposes at least one test point on the sample wafer and performs preliminary electrical measurements on the test point, such as a capacitance measurement, a current measurement, a voltage measurement, and a resistance measurement. The manufacturer uses the measurement results as WAT sample data. In this case, the machine learning model calculates the WAT sample data of the sample wafer and predicts a process factor for each sample die. In some embodiment, the process factors at least comprises the drain current (Idsat) of a MOS transistor operating in a saturation region, the threshold voltage (Vth) of the MOS transistor or the leakage current (Ioff) of the turned-off MOS transistor, the capacitance of a metal-oxide-metal (MOM) capacitor, and a resistance of the non-silicide resistor.

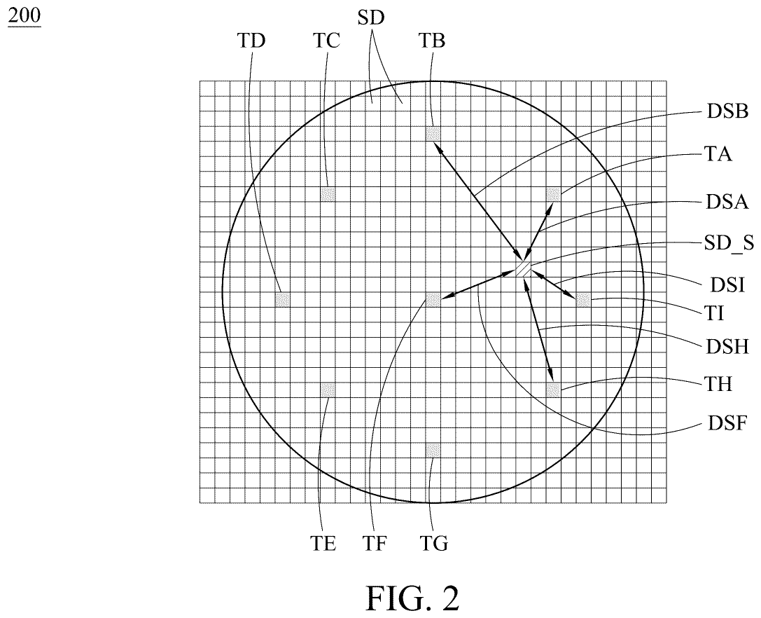

In other embodiments, step S111 further inputs a wafer map of the sample wafer into the machine learning model. FIG. 2 is a schematic diagram of an exemplary embodiment of a wafer map according to various aspects of the present disclosure. The wafer map 200 shows the locations of all sample dies SD and the locations of test points TA-TI on the sample wafer. In this case, the WAT sample data records the process factors of the test points TA-TI.

The machine learning model predicts the process factor of each sample die according to the wafer map 200 and the WAT sample data. In one embodiment, the machine learning model calculates the relative distance between each sample die SD and at least one test point. The machine learning model establishes at least one correlation between the relative distance and the process factors of the corresponding test point. In this case, the machine learning model predicts the process factors of each sample die according to the correlations.

Taking the sample die SD_S as an example, assumed that the machine learning model calculates the relative distance DSA between the sample die SD_S and the test point TA and establishes a first correlation between the relative distance DSA and the process factors of the corresponding test point TA. The machine learning model further calculates the relative distance DSB between the sample die SD_S and the test point TB and establishes a second correlation between the relative distance DSB and the process factors of the corresponding test point TB. The machine learning model further calculates the relative distance DSF between the sample die SD_S and the test point TF and establishes a third correlation between the relative distance DSF and the process factors of the corresponding test point TF. The machine learning model further calculates the relative distance DSH between the sample die SD_S and the test point TH and establishes a fourth correlation between the relative distance DSH and the process factors of the corresponding test point TH. The machine learning model further calculates the relative distance DSI between the sample die SD_S and the test point TI and establishes a fifth correlation between the relative distance DSI and the process factors of the corresponding test point TI. The machine learning model predicts the process factors of the sample die SD_S according to the first, second, third, fourth and fifth correlations.

In other embodiments, the machine learning model calculates the relative distances between the sample die SD_S and more or fewer test points. The present disclosure does not limit how the machine learning model establishes the correlation between the sample die SD_S and at least one test point. In some embodiments, because the relative distance DSA is less than the relative distances DSB, DSF, DSH, and DSI, the process factors of the sample die SD_S may be close to the process factors of the test point TA. Therefore, the machine learning model may predict the process factors of the sample die SD_S according to the relative distance DSA and the process factors of the test point TA.

Then, in a test mode, a test operation is performed on a wafer to be tested (step S120). The wafer to be tested comprises a plurality of dies to be tested. In one embodiment, the wafer to be tested and the sample wafer have the same specifications. First, the WAT data of the wafer to be tested is input into the trained machine learning model to predict at least one process factor of each dies to be tested (step S121). In one embodiment, step S121 is performed to further input the wafer map of the wafer to be tested into the machine learning model. In this case, since the wafer to be tested and the sample wafer have the same specifications, the wafer map of the wafer to be tested is the same as the wafer map of the sample wafer. In some embodiments, step S121 writes the process factors of each dies to be tested into the corresponding dies to be tested.

Then, the process factors of each die to be tested are converted to generate a trim value, and each trim value is provided to the corresponding die to be tested (step S122). In one embodiment, step S122 stores each trim value to the corresponding die to be tested. In this case, at least one function circuit in the die to be tested operates according to the corresponding trim value.

Next, it is determined whether the output of a predetermined function circuit (or referred to as a first function circuit) in each die to be tested meets a test rule (step S123). In one embodiment, each die to be tested comprises multiple function circuits. The present disclosure does not limit the type and number of function circuits in the die to be tested. Any electronic circuit can be disposed in the die to be tested.

When the outputs of the predetermined function circuits of the dies to be tested meet the test rule, the test operation S120 is finished. However, when the output of the predetermined function circuit of a die to be tested does not meet the test rule, the trim value of the predetermined function circuit of the die to be tested is adjusted (step S124), and then it is re-determined whether the output of the predetermined function circuit in the die to be tested meets the test rule (step S123).

Since the trained machine learning model predicts the trim values, the outputs of most of the predetermined function circuits should meet the test rule. Even if the outputs of a small number of predetermined function circuits do not meet the test rule, only the trim values of those small number of predetermined function circuits need to be corrected. Therefore, the test time is reduced, the test costs are reduced, and the product quality is improved.

FIG. 1B is a flowchart of another exemplary embodiment of the test method according to various aspects of the present disclosure. FIG. 1B is similar to FIG. 1A except for the addition of steps S112˜S114. After predicting the process factors of the sample dies, the machine learning model converts the process factors of each sample die to generate at least one trim value, and provides each trim value to the corresponding sample die (step S112). In one embodiment, step S112 is performed to write each trim value into a corresponding sample die.

In some embodiments, a function circuit (or referred to as a second function circuit) in each sample die generates an output signal according to the trim value. The present disclosure does not limit the type of the second function circuit. In one embodiment, the second function circuit is a resistor-capacitor oscillator circuit (RC oscillator). In this case, each sample die comprises a resistor-capacitor oscillator circuit. The resistor-capacitor oscillator circuit of each sample die generates a clock signal according to the trim value generated in step S112.

Next, it is determined whether the yield of the sample die is greater than a target value (step S113). In an embodiment, step S113 is performed to determine whether the frequency of the output signal of the second function circuit meets a predetermined value. When the frequency of the output signal of the second function circuit of a sample die meets a predetermined value, it indicates that the sample die is a good product. However, when the frequency of the output signal of the second function circuit of a sample die does not meet a predetermined value, it indicates that the sample die is a defective product. When the number of defective products is lower than a threshold value, it indicates that the yield of the sample die is greater than the target value. Therefore, a test operation S120 is started on a wafer to be tested. When the number of defective products is higher than the threshold value, it indicates that the yield of the sample die is not greater than the target value. Therefore, the factors of the machine learning model are adjusted (step S114) until the yield of the sample die is greater than a target value.

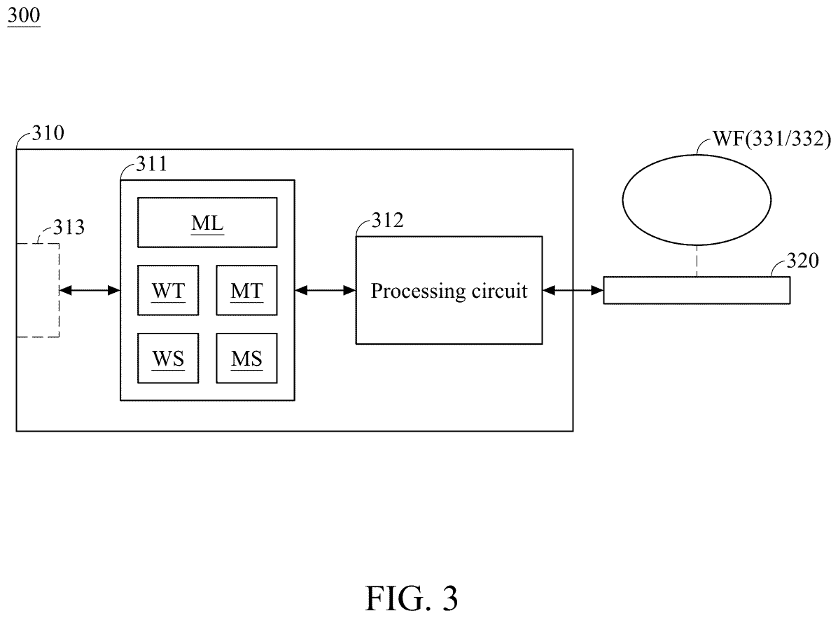

FIG. 3 is a schematic diagram of an exemplary embodiment of a test system according to various aspects of the present disclosure. As shown in FIG. 3, the test system 300 comprises a test device 310 and a test platform 320. A wafer WF is disposed on the test platform 320. During a training period, a tester (or a robot arm) places a sample wafer 331 on the test platform 320. During a test period, a wafer 332 to be tested is placed on the test platform 320.

The test device 310 is electrically connected to the wafer WF via the test platform 320. During a training period, the test device 310 uses the sample wafer 331 to perform a training operation on a machine learning model ML. During a test period, the test device 310 uses the trained machine learning model ML to perform a test operation on the wafer 332 to be tested. In this embodiment, the test device 310 comprises a storage circuit 311 and a processing circuit 312.

The storage circuit 311 stores a machine learning model ML. In some embodiments, the storage circuit 311 further stores the WAT sample data WS and a wafer map MS of the sample wafer 331 and the WAT data WT and a wafer map MT of the wafer 332 to be tested. In one embodiment, when the sample wafer 331 and the wafer 332 to be tested have the same specifications, the wafer map MS is the same as the wafer map MT.

In other embodiments, the test device 310 further comprises an input-output interface 313. The input-output interface 313 receives external data and writes the external data into the storage circuit 311. In one embodiment, the external data comprises at least one of the machine learning model ML, the WAT sample data WS, the wafer map MS, the WAT data WT, and the wafer map MT. In some embodiments, the input-output interface 313 further outputs the test results of the wafer 332 to be tested.

In a training mode, a sample wafer 331 is placed on the test platform 320. The sample wafer 331 comprises a plurality of sample dies. The processing circuit 312 uses the sample wafer 331 to perform a training operation on the machine learning model ML. In this mode, the processing circuit 312 accesses the storage circuit 311 to load the machine learning model ML. The processing circuit 312 inputs the WAT sample data WS into the machine learning model ML to train the machine learning model ML to predict the process factor of each sample die.

In another embodiment, the processing circuit 312 inputs the WAT sample data WS and the wafer map MS into the machine learning model ML. In this case, the machine learning model ML calculates the WAT sample data WS and the wafer map MS to predict the process factors of all sample dies on the sample wafer 331.

The present disclosure does not limit how the machine learning model ML calculates the WAT sample data WS and the wafer map MS. In one embodiment, the machine learning model ML obtains the relative distance between each sample die and at least one test point of the sample wafer 331 according to the wafer map MS and the WAT sample data WS, and establishes a plurality of correlations between the relative distances and the process factors of the test point. In this case, the machine learning model ML predicts the process factors of each sample die according to these correlations.

After completing the training operation, the processing circuit 312 writes the trained machine learning model ML into the storage circuit 311 and enters a test mode. In the test mode, the wafer 332 to be tested is placed on the test platform 320. The wafer 332 to be tested 332 comprises a plurality of dies to be tested. The processing circuit 312 uses the trained machine learning model ML to perform a test operation on the wafer 332 to be tested. In this mode, the processing circuit 312 accesses the storage circuit 311 to load the trained machine learning model ML and inputs the WAT data WT into the machine learning model ML to predict at least one process factor of each die to be tested on the wafer 332 to be tested.

In one embodiment, the processing circuit 312 further inputs the wafer map MT into the machine learning model ML. The machine learning model ML calculates the WAT data WT and the wafer map MT to predict at least one process factor of each die to be tested. In some embodiments, the processing circuit 312 writes each process factor into the corresponding die to be tested. In this case, each die to be tested comprises a non-volatile memory (NVM) for storing the process factor.

In the test mode, the processing circuit 312 converts the process factors of each die to be tested to generate at least one trim value and provides the trim value to a function circuit (or referred to as a first function circuit) of a corresponding die to be tested. In one embodiment, the processing circuit 312 writes each trim value into the non-volatile memory of the corresponding die to be tested.

The first function circuit of each die to be tested operates according to the corresponding trim value. In the test mode, the processing circuit 312 determines whether the output of each first function circuit meets a test rule. When the output of a specific circuit of the first function circuits does not meet the test rule, the processing circuit 312 adjusts the trim value of the specific circuit.

In other embodiments, in the training mode, the processing circuit 312 converts the process factors of each sample die to generate at least one trim value, and writes each trim value into the corresponding sample die. In this case, a function circuit (or referred to as a second function circuit) of each sample die generates an output signal according to the corresponding trim value. The processing circuit 312 determines whether the yield of the sample die is greater than a target value according to the output signal of each sample die. The present disclosure does not limit the type of the second function circuit. In one embodiment, the second function circuit is a resistor-capacitor oscillator circuit. The resistor-capacitor oscillator circuit generates a clock signal according to the corresponding trim value.

The present disclosure does not limit how the processing circuit 312 determines whether the yield of the sample die is greater than a target value. In one embodiment, the processing circuit 312 determines whether the output signal of each sample die meets a predetermined value. When the output signal of a sample die meets a predetermined value, it indicates that the sample die is a good product. When the output signal of a sample die does not meet a predetermined value, it indicates that the sample die is a defective product. In this case, the processing circuit 312 determines whether the number of defective products is lower than a threshold value. When the number of defective products is lower than a threshold value, it indicates that the yield of the sample die is greater than a target value. Therefore, the processing circuit 312 enters the test mode. When the number of defective products is higher than the threshold value, it indicates that the yield of the sample die is not greater than a target value. Therefore, the processing circuit 312 adjusts the factors of the machine learning model ML until the yield of the sample die is greater than the target value.

The machine learning model ML trained by the processing circuit 312 is used to predict the process factors of each die of the wafer 332 to be tested, and then these process factors are converted into the trim values of the function circuits of the die of the wafer 332 to be tested. The trim values are written into the function circuits of the wafer 332 to be tested. Most of the function circuits can pass the test. The function circuits of some dies cannot pass the test. The processing circuit 312 then fine-tunes the corresponding trim value so that the function circuits of some dies also pass the test. Therefore, the test time of the wafer to be tested is greatly shortened, the test cost is reduced and the quality of the product is improved.

Test transmission methods, or certain aspects or portions thereof, may take the form of a program code (i.e., executable instructions) embodied in tangible media, such as floppy diskettes, CD-ROMS, hard drives, or any other machine-readable storage medium, wherein, when the program code is loaded into and executed by a machine such as a computer, the machine thereby becomes a test device and a test system for practicing the methods. The methods may also be embodied in the form of a program code transmitted over some transmission medium, such as electrical wiring or cabling, through fiber optics, or via any other form of transmission, wherein, when the program code is received and loaded into and executed by a machine such as a computer, the machine becomes a test device and a test system for practicing the disclosed methods. When implemented on a general-purpose processor, the program code combines with the processor to provide a unique apparatus that operates analogously to application-specific logic circuits.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein. It will be understood that although the terms “first,” “second,” etc. may be used herein to describe various elements, these elements should not be limited by these terms. These terms are only used to distinguish one element from another.

While the disclosure has been described by way of example and in terms of the preferred embodiments, it should be understood that the disclosure is not limited to the disclosed embodiments. On the contrary, it is intended to cover various modifications and similar arrangements. Therefore, the scope of the appended claims should be accorded the broadest interpretation so as to encompass all such modifications and similar arrangements.

What is claimed is:

1. A test device, comprising:
a storage circuit storing a machine learning model; and
a processing circuit accessing the storage circuit,
wherein:
in a training mode:
the processing circuit is electrically connected to a sample wafer which comprises a plurality of sample dies;
the processing circuit loads the machine learning model and inputs wafer acceptance test (WAT) sample data of the sample wafer into the machine learning model to train the machine learning model to predict a process factor of each sample die of the sample wafer,
in a test mode:
the processing circuit is electrically connected to a wafer which is to be tested and which comprises a plurality of dies to be tested,
the processing circuit inputs WAT data of the wafer to be tested into the machine learning model to predict a process factor of each die to be tested,
the processing circuit converts the process factor of each die to be tested to generate a trim value and provides the trim value to a first function circuit of a corresponding die to be tested.

2. The test device as claimed in claim 1, wherein in the training mode:
the processing circuit converts the process factor of each sample die to generate a trim value and writes the trim value to a corresponding sample die,
a second function circuit of each sample die operates according to a corresponding trim value to generate an output signal,
the processing circuit determines whether the yields of the sample dies are greater than a target value, and
in response to the yields of the sample dies being greater than the target value, the processing circuit enters the test mode.

3. The test device as claimed in claim 2, wherein:
the storage circuit further stores the WAT sample data and a wafer map, and
in the training mode, the processing circuit inputs the WAT sample data and the wafer map into the machine learning model to train the machine learning model to predict the process factor of each sample die.

4. The test device as claimed in claim 3, wherein in the training mode, in response to the yields of the sample dies not being greater than the target value, the processing circuit adjusts a factor of the machine learning model.

5. The test device as claimed in claim 3, wherein:
the WAT sample data records a process factor of a test point of the sample wafer,
the machine learning model obtains a relative distance between each sample die and the test point according to the wafer map and the WAT sample data, and establishes a correlation between each relative distance and the process factor of the test point, and
the machine learning model predicts the process factor of each sample die according to the correlations.

6. The test device as claimed in claim 5, wherein:
the storage circuit further stores the WAT data, and
in the test mode, the processing circuit inputs the WAT data of the wafer to be tested and the wafer map of the sample wafer into the machine learning model.

7. The test device as claimed in claim 3, wherein the second function circuit is a resistor-capacitor oscillator circuit.

8. The test device as claimed in claim 7, wherein in the test mode, the processing circuit writes one of the trim values to a corresponding die to be tested and writes one of the process factors to a corresponding die to be tested.

9. The test device as claimed in claim 8, wherein in the test mode, each first function circuit operates according to a corresponding trim value.

10. The test device as claimed in claim 9, wherein in the test mode:
the processing circuit determines whether an output of each first function circuit meets a test rule, and
in response to the output of a specific circuit among the first function circuits not meeting the test rule, the processing circuit adjusts the trim value of the specific circuit.

11. A test method, comprising:
in a training mode:
electrically connecting to a sample wafer which comprises a plurality of sample dies; and
inputting WAT sample data of the sample wafer into a machine learning model to train the machine learning model to predict a process factor of each sample die; and
in a test mode:
electrically connecting to a wafer which is to be tested and which comprises a plurality of dies to be tested;
inputting WAT data of the wafer to be tested into the machine learning model so that the machine learning model predicts a process factor of each die to be tested;
converting the process factor of each die to be tested to generate a trim value; and
providing the trim value to a first function circuit of a corresponding die to be tested.

12. The test method as claimed in claim 11, further comprising:
in the test mode:
converting the process factor of each sample die to generate a trim value;
providing each trim value to a second function circuit of a corresponding sample die, wherein the second function circuit generates an output signal according to a corresponding trim value;
determining whether the yields of the sample dies are greater than a target value according to the output signals; and
entering the test mode in response to the yields of the sample dies being greater than the target value.

13. The test method as claimed in claim 12, further comprising:
in the test mode:
inputting the WAT sample data and a wafer map of the sample wafer into the machine learning model to train the machine learning model to predict a process factor of each sample die.

14. The test method as claimed in claim 13, further comprising:
in the training mode:
adjusting a factor of the machine learning model in response to the yields of the sample dies not being greater than the target value.

15. The test method as claimed in claim 14, wherein:
the machine learning model obtains a relative distance between each sample die and a test point according to the wafer map and the WAT sample data, and establishes a correlation between each relative distance and the process factor of the test point, and
the machine learning model predicts the process factor of each sample die according to the correlations.

16. The test method as claimed in claim 15, further comprising:
in the test mode:
inputting the WAT data of the wafer to be tested and the wafer map of the sample wafer into the machine learning model.

17. The test method as claimed in claim 13, wherein the output signals are clock signals.

18. The test method as claimed in claim 17, further comprising:
in the test mode:
writing one of the trim values to a corresponding die to be tested; and
writing one of the process factors to a corresponding die to be tested.

19. The test method as claimed in claim 18, further comprising:
in the test mode:
determining whether an output of each first function circuit meets a test rule; and
adjusting the trim value of a specific circuit among the first function circuits in response to an output of the specific circuit not meeting the test rule.

20. A test system, comprising:
a test platform configured to dispose a sample wafer or a wafer to be tested;
a storage circuit storing a machine learning model; and
a processing circuit accessing the machine learning model,
wherein:
in a training mode:
the sample wafer is disposed on the test platform,
the processing circuit is electrically connected to the sample wafer which comprises a plurality of sample dies; and
the processing circuit loads the machine learning model and inputs WAT sample data of the sample wafer into the machine learning model to train the machine learning model to predict a process factor of each sample die, and
in a test mode:
the wafer to be tested is disposed on the test platform,
the processing circuit is electrically connected to the wafer which is to be tested and which comprises a plurality of dies to be tested,
the processing circuit inputs WAT data of the wafer to be tested into the machine learning model to predict a process factor of each die to be tested, and
the processing circuit converts the process factor of each die to be tested to generate a trim value and provides the trim value to a first function circuit of a corresponding die to be tested.
